(19) United States
(12) Patent Application Publication
(10) Pub. No.: US 2008/0073735 A1
(43) Pub. Date: Mar. 27, 2008

(54) Image sensor and fabrication method thereof

(75) Inventor: Joon Hwang, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/897,671

(22) Filed: Aug. 31, 2007

(30) Foreign Application Priority Data
Sep. 26, 2006 (KR) 10-2006-0093576

(51) Int. Cl. H01L 31/0232; H01L 21/02

(52) U.S. Cl. 257/432; 438/70; 257/E31.053; 257/E21.243

(57) ABSTRACT

An image sensor comprises a lower structure having at least one photodiode and interconnection, a passivation layer on the lower structure, a color filter array on the passivation layer, and a micro-lens array comprising an oxide layer on the color filter array.

The present application claims priority under 35 U.S.C. 119 and 35 U.S.C. 365 to Korean Patent Application No. 10-2006-0093576 (filed on Sep. 26, 2006), which is hereby incorporated by reference in its entirety.

### BACKGROUND

Embodiments of the invention relate to an image sensor and a method of fabricating the same.

The image sensor refers to a semiconductor device that converts an optical image into an electrical signal. This image sensor includes a micro-lens array for collecting and focusing incident light onto a photodiode.

One of the problems to be solved when the image sensor is fabricated is to increase a rate of converting an incident light signal into an electrical signal (e.g., improve the sensitivity of the image sensor).

Further, in forming the micro-lens array for collecting light, a variety of attempts are being made to find a method of realizing a zero gap (e.g., that provides no gap between neighboring lenses in the micro-lens array).

Meanwhile, there is a phenomenon that a capping layer is separated from a pad region that must be opened for connecting a signal with an external lead or trace due to a stress difference between layers.

Furthermore, there is another phenomenon that polymer particles caused by, for instance, an exposed photosensitive layer can attach to the micro-lens array in processes such as a wafer back-grinding process and a packing process. This phenomenon is responsible not only for reducing the sensitivity of the image sensor but also for lowering a fabrication yield due to difficulty of cleaning, etc.

### SUMMARY

Embodiments of the invention provide an image sensor and a method of fabricating the same, capable of improving sensitivity and fabrication yield of the same.

One embodiment of the invention provides an image sensor. The image sensor comprises a lower structure having at least one photodiode and interconnection, a passivation layer on the lower structure, a color filter array on the passivation layer, and a micro-lens array comprising an oxide layer on the color filter array.

Another embodiment provides a method of fabricating an image sensor. The method comprises forming a passivation layer on a lower structure having at least one photodiode and interconnection, forming a color filter array on the passivation layer, forming a low temperature oxide (LTO) layer on the color filter array, forming a patterned photosensitive layer on the LTO layer, and wet etching the LTO layer to form a micro-lens array.

### BRIEF DESCRIPTION OF THE DRAWINGS

FIGS. 1 through 7 illustrate a method of fabricating an image sensor according to an embodiment.

### DETAILED DESCRIPTION OF THE EMBODIMENTS

In the description of an embodiment, it will be understood that, when a layer (or film), a region, a pattern, or a structure is referred to as being “on/above” or “under/below” another substrate, another layer (or film), another region, another pad, or another pattern, it can be directly on the other substrate, layer (or film), region, pad, or pattern, or intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by technical idea of the invention.

Hereinafter, one or more embodiments of the invention will be described in detail with reference to the accompanying drawings.

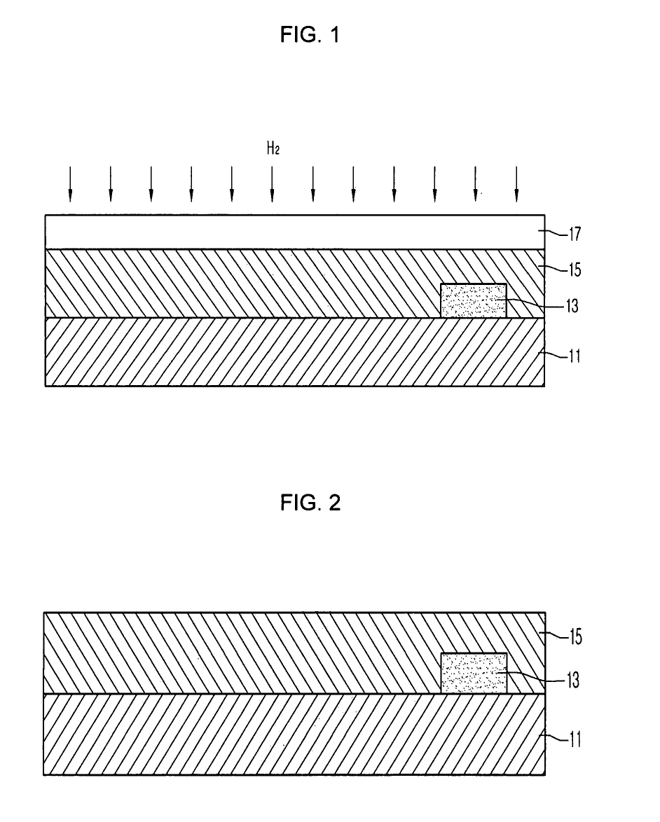

An exemplary method of fabricating an image sensor will be described with reference to FIGS. 1 through 7. FIGS. 1 through 7 schematically illustrate a method of fabricating an image sensor according to various embodiments of the invention.

In the exemplary method of fabricating an image sensor as illustrated in FIG. 1, a passivation layer is formed on a lower structure 11 having at least one photodiode and interconnection. Preferably, the lower structure has a plurality of photodiodes, each corresponding to a microlens in the microlens array. A pad 13 for connecting an image sensor signal with the outside is formed on the lower structure 11, and the passivation layer is formed on or over the pad 13.

The passivation layer may comprise an oxide layer 15 (e.g., silicon dioxide, such as an undoped silicate glass [USG]) and/or a nitride layer 17 (e.g., silicon nitride). In forming the passivation layer, in one embodiment, the oxide layer 15 is formed on the lower structure 11, and then the nitride layer 17 is formed on the oxide layer 15. In the case in which the passivation layer comprises the nitride layer 17, H₂ annealing is performed on the nitride layer 17, to remove defects from the nitride layer 17. The annealing can also be performed in an atmosphere containing other reducing agents, such as NH₃ and/or SiH₄, optionally in the presence of an inert gas, such as Ar, He, Ne or N₂. Thus, it is possible to improve a characteristic of low illuminance of the image sensor to be fabricated. The nitride layer 17 can be made of material based on SiN. For example, dangling bonds can be removed by the annealing process. Further, the annealing process can prevent cracks from forming in the oxide layer 15 due to a stress difference between the oxide layer and a low temperature oxide (LTO) layer that will be subsequently formed.

Then, as illustrated in FIG. 2, the nitride layer 17 is removed to expose the oxide layer 15. In removing the nitride layer 17, the nitride layer 17 can be removed by an etch back process or a chemical mechanical polishing (CMP) process. At this time, the oxide layer 15 remains on the pad 13. As a result, the pad 13 can be protected by the oxide layer 15 without exposure.

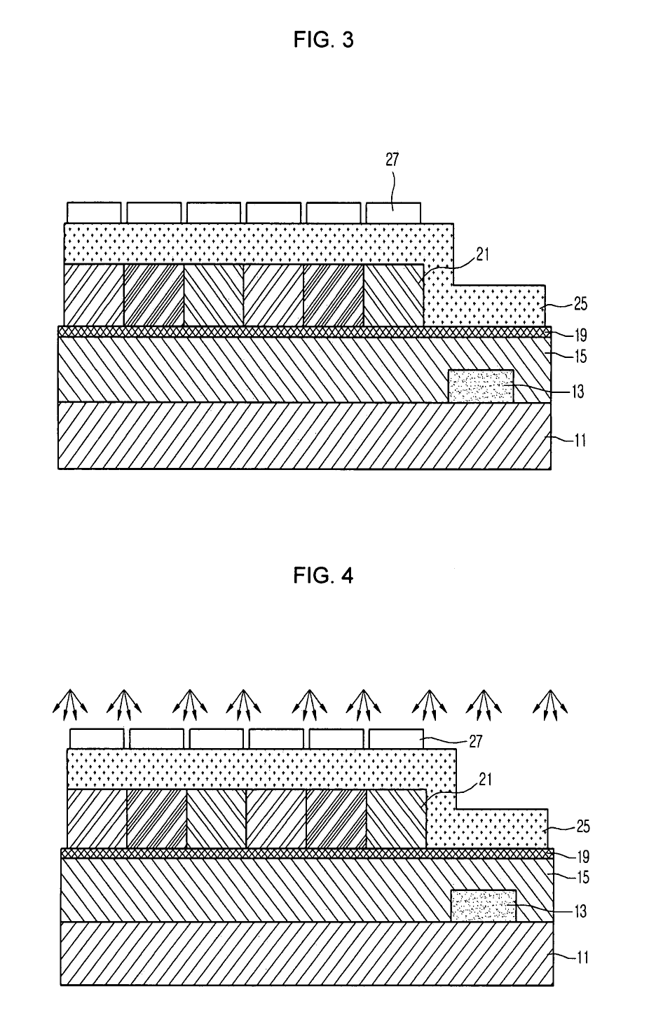

Afterwards, as illustrated in FIG. 3, a thermosetting resin layer 19 is formed on the exposed oxide layer 15. Thereby, it is possible to reduce defects from the oxide layer 15. Further, it is possible improve adhesiveness of the oxide layer 15 with a layer that will be subsequently formed on the thermosetting resin layer. Meanwhile, the process of forming the thermosetting resin layer 19 can be omitted depending on a design of the image sensor.

In the exemplary method of fabricating an image sensor as illustrated in FIG. 3, the process of forming a color filter array 21 on the thermosetting resin layer 19 is performed. The color filter array 21 may contain a plurality of color filters, each color filter being positioned between a subsequently formed microlens and the corresponding photodiode, and being configured to filter light other than that of a predetermined color or band of light wavelengths. For example, the color filter array 21 may include red, green and blue color filters (e.g., a RGB system) or yellow, cyan and magenta color filters (a YCM system).

Further, the process of forming an oxide layer on the color filter array 21 is performed. The oxide layer can comprise or consist essentially of a low temperature oxide (LTO) layer 25.

The LTO layer 25 can be also formed above the pad 13. At this time, the oxide layer 15, the thermosetting resin layer 19, and the LTO layer 25 are sequentially stacked on the pad 13.

The LTO layer 25 may have a thickness from about 3,000 Å to about 10,000 Å. The LTO layer 25 can be formed so as to be thicker than the micro-lens array since the micro-lens array will be subsequently formed from the LTO layer 25 by an etching process. For example, the LTO layer 25 can have a thickness from 1.5 to 3 times (e.g., about two times) as thick as the subsequently formed micro-lens array.

The LTO layer 25 can be formed under a temperature of 200° C. by plasma-enhanced chemical vapor deposition (PECVD) of one or more silicon dioxide precursors, such as silane (SiH₄) or tetraethylorthosilicate (TEOS), in the presence of oxygen (O₂) and/or ozone (O₃). As one example, the LTO layer 25 can be formed within a temperature range from 150° C. to 200° C. by PECVD. In this manner, because the LTO layer 25 is formed at a relatively low temperature, deterioration of the color filter array 21 can be reduced or prevented.

Then, a first photosensitive layer pattern 27 for forming a micro-lens array is formed on the LTO layer 25. As one example, the first photosensitive layer pattern 27 can be formed by forming (e.g., depositing or spin-coating) a photosensitive layer on the LTO layer 25 and then patterning the first photosensitive layer through a photolithography process.

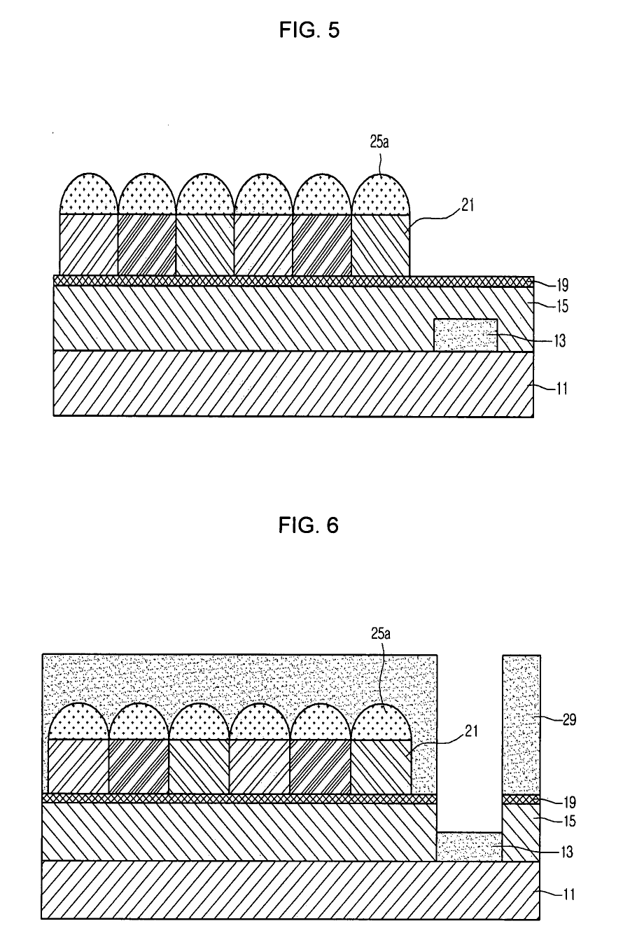

Thereafter, the first photosensitive layer pattern 27 is heated to reflow the first photosensitive layer pattern 27 into a convex or curved shape of a microlens, then the first photosensitive layer pattern 27 and the underlying LTO layer 25 are non-selectively etched to impart or transfer the convex or curved microlens shape to the underlying LTO layer 25. While nonselective etching may comprise wet or dry etching, wet etching is preferred. Wet etching causes the first photosensitive layer pattern 27 and the LTO layer 25 to undergo isotropic etching. As a result, as illustrated in FIG. 5, a micro-lens array 25a is formed from LTO layer 25.

The micro-lens array 25a formed through the etching of the LTO layer 25 can have a zero gap. In other words, the micro-lens array 25a can has no gap or space between neighboring microlenses, at least at one or more contact points along a horizontal and/or vertical direction (e.g., row and/or column) of micro-lens array 25a.

Further, according to an embodiment, because the micro-lens array 25a is formed from the LTO layer 25, it is possible to prevent foreign materials (e.g., polymer particles, etc.) from attaching to the micro-lens array 25a in subsequent processing, such as a packaging process.

Thereafter, in the method of fabricating an exemplary image sensor, as illustrated in FIG. 6, the micro-lens array 25a, the thermosetting resin layer 19, and the oxide layer 15 may be etched (preferably following photolithographic patterning of a photoresist) to expose the pad 13 on the lower structure 11. As one example, this process can expose the pad 13 by forming a second photosensitive layer pattern 29 on the micro-lens array 25a and then irradiating and either etching or developing the second photosensitive layer pattern 29. In this method of fabricating an image sensor according to various embodiments, when the pad 13 is exposed, the exposure can easily occur through a pad open process at one time.

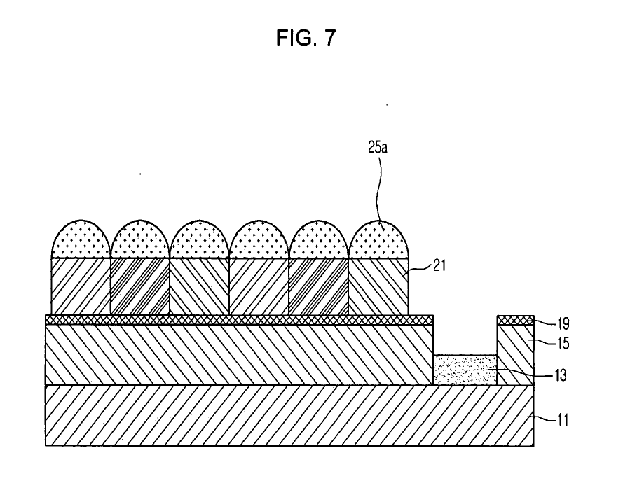

Afterwards, the second photosensitive layer pattern 29 is removed, so that the exemplary image sensor can be obtained as illustrated in FIG. 7.

Meanwhile, the process of forming the micro-lens array 25a of an oxide layer has been described with reference to FIGS. 3, 4 and 5 taking the case of performing the isotropic (e.g., wet) etching on the first photosensitive layer pattern 27, by way of example. However, if necessary, a heat-treatment process may be further performed before the wet etching is performed on the first photosensitive layer pattern 27. As one example, the heat-treatment process includes a reflow process. This heat-treatment process allows the first photosensitive layer pattern 27 to have a lens-shaped curvature. As a result, the micro-lens array 25a in which the lens shape of the first photosensitive layer pattern 27 is reflected or reproduced can be obtained.

As described above, the present image sensor, which can be fabricated by the present method of fabricating an image sensor according to various embodiments, comprises the lower structure 11 having at least one photodiode and interconnection, the passivation layer (e.g., comprising the oxide layer) formed on the lower structure 11, and the pad 13 formed on the lower structure 11, which functions to connect a signal with the outside. Further, the present image sensor may comprise the thermosetting resin layer 19 formed on the oxide layer 15, and the color filter array 21 formed on the thermosetting resin layer 19. Meanwhile, the thermosetting resin layer 19 may not be formed depending on a design of the image sensor. The present image sensor further comprises the micro-lens array 25a (e.g., comprising an oxide layer) formed on the color filter array 21. The micro-lens array 25a can comprise or consist essentially of an LTO layer.

The micro-lenses in the array 25a (comprising a LTO layer) can have the convex or curved shape of a lens, and the array 25a can have a zero gap. The micro-lens array 25a can easily realize the zero gap that provides no gap between the neighboring lenses, even if the photoresist from which the lens shape was transferred has a small gap between the lens shapes thereof as long as the entire thickness of the LTO layer is not etched.

One embodiment of the invention may prevent a phenomenon in which an insulator layer is separated from the pad due to a stress difference between the insulator layer and either the pad or an overlying layer.

Further, a phenomenon that polymer particles caused by, for instance, a photosensitive layer attach to the micro-lens array in processes such as a wafer back-grinding process and/or a packaging process can be prevented. As a result, it is possible not only to reduce or prevent the reduction of the sensitivity of the image sensor but also increase the fabrication yield.

As described above, according to the present image sensor and the method of fabricating the same, the sensitivity and fabrication yield of the image sensor can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a lower structure having at least one photodiode and an interconnection;
a passivation layer on the lower structure;
a color filter array on the passivation layer; and
a micro-lens array comprising a first oxide layer on the color filter array.

2. The image sensor as claimed in claim 1, wherein the passivation layer includes a second oxide layer.

3. The image sensor as claimed in claim 1, further comprising a thermosetting resin layer between the passivation layer and the color filter array.

4. The image sensor as claimed in claim 1, wherein the micro-lens array comprises a low temperature oxide (LTO) layer.

5. The image sensor as claimed in claim 4, wherein the micro-lens array consists essentially of a low temperature oxide (LTO) layer.

6. The image sensor as claimed in claim 1, wherein the micro-lens array has a zero gap between neighboring microlenses.

7. A method of fabricating an image sensor, the method comprising:
forming;
forming a passivation layer on a lower structure having at least one photodiode and an interconnection therein;
forming a color filter array on the passivation layer;
forming a low temperature oxide (LTO) layer on the color filter array;
forming a patterned photosensitive layer on the LTO layer; and
wet etching the LTO layer to form a micro-lens array.

8. The method as claimed in claim 7, wherein forming the passivation layer comprises:
forming an oxide layer on the lower structure;
forming a nitride layer on the oxide layer;
annealing the nitride layer in an atmosphere containing a reducing agent; and
removing the nitride layer to expose the oxide layer.

9. The method as claimed in claim 8, further comprising forming a thermosetting resin layer on the exposed oxide layer.

10. The method as claimed in claim 8, wherein removing the nitride layer comprises an etch back process.

11. The method as claimed in claim 8, wherein removing the nitride layer comprises a chemical mechanical polishing (CMP) process.

12. The method as claimed in claim 7, wherein the LTO layer has a thickness from about 3,000 Å to about 10,000 Å.

13. The method as claimed in claim 7, wherein the micro-lens array has a zero gap.

14. The method as claimed in claim 7, wherein forming the LTO layer comprises plasma-enhanced chemical vapor deposition (PECVD).

15. The method as claimed in claim 7, further comprising performing heat treatment on the patterned photosensitive layer after forming the patterned photosensitive layer.

16. The method as claimed in claim 7, further comprising etching the passivation layer to expose a pad on the lower structure after etching the LTO layer to form the micro-lens array.

17. The method as claimed in claim 7, further comprising forming the lower structure having at least one photodiode and the interconnection therein.

18. The method as claimed in claim 17, wherein the lower structure has a plurality of photodiodes, each photodiode corresponding to a unique microlens in the array.

19. The method as claimed in claim 7, wherein forming the patterned photosensitive layer comprises depositing a photoresist on the LTO layer, patterning the photoresist, and reflowing the patterned photoresist.

20. The method as claimed in claim 8, wherein the reducing agent comprises H₂, NH₃, or SiH₄.
